(19) United States
(12) Patent Application Publication
(10) Pub. No.: US 2026/0081559 A1
(43) Pub. Date: Mar. 19, 2026

(54) PHOTOVOLTAIC ASSEMBLY

(71) Applicant: SHENGDA XU, NANJING (CN)

(72) Inventor: SHENGDA XU, NANJING (CN)

(21) Appl. No.: 19/395,188

(22) Filed: Nov. 20, 2025

Related U.S. Application Data
(63) Continuation of application No. PCT/CN2024/093856, filed on May 17, 2024.

(30) Foreign Application Priority Data
May 24, 2023 (CN) 202321284854.8
Nov. 9, 2023 (CN) 202323050429.5

(51) Int. Cl. H02S 40/42; H02S 40/32; H02S 40/34; H02S 40/38; H10F 77/63

(52) U.S. Cl. CPC H02S 40/425; H02S 40/32; H02S 40/34; H02S 40/38; H10F 77/68

(57) ABSTRACT

A photovoltaic assembly includes a photovoltaic module and a heat dissipation module. The heat dissipation module is configured to be connected to an external object. The photovoltaic module includes a light-incident side configured to receive sunlight and a back side opposite to the light-incident side. The photovoltaic module is configured to convert the sunlight to electrical energy. The heat dissipation module is arranged on the back side of the photovoltaic module and configured to dissipate heat generated by the photovoltaic module.

### CROSS-REFERENCE TO RELATED APPLICATIONS

This application is a continuation of International Application No. PCT/CN2024/093856, filed on May 17, 2024, which claims priority to Chinese Patent Application No. 2023212848548, filed on May 24, 2023, and Chinese Patent Application No. 2023230504295, filed on Nov. 9, 2023, the entire contents of which are incorporated herein by reference.

### FIELD

The present disclosure relates to photovoltaic technology, and in particular, to a photovoltaic assembly.

### BACKGROUND

With increasing emphasis on clean energy and the development of solar photovoltaic technology, solar photovoltaic assemblies are used more widely in daily life, especially in buildings.

When photovoltaic (PV) assemblies are used in buildings, they are generally installed in a closed manner or directly glued to the buildings. In addition, PV assemblies generate heat when they receive solar energy and convert it into electrical energy. The high degree of sealing of PV modules leads to poor heat dissipation efficiency, which affects power generation efficiency of PV modules and increases heat load of the buildings, thus causing certain damage to the buildings.

In addition, the crystalline silicon solar photovoltaic assemblies currently widely used in the market are generally single-glass or double-glass modules encapsulated with tempered glass. This makes the photovoltaic assemblies heavy while meeting requirements of rigidity, resulting in inconvenience in handling and installation, higher costs, and an application range of this type of solar photovoltaic assemblies is limited to installation on flat surfaces such as the ground and a roof.

However, when solar photovoltaic assemblies need to be installed on curved surfaces such as curved buildings, smooth vertical walls such as glass walls, or equipment such as yachts and cars, heavy weight makes installation difficult and fit is poor, which limits application scenarios of photovoltaic assemblies.

Although flexible solar photovoltaic assemblies have emerged on the market, which have good bendability and are easy to carry due to their light weight, making them suitable for installation in some special locations such as curved surfaces or equipment surfaces, however, rigidity of the flexible solar photovoltaic assemblies cannot meet the installation requirements, such as in the buildings, thus limiting the scope of installation and use of the products.

### SUMMARY

In order to solve shortcomings in existing technologies, the present disclosure is to provide a photovoltaic assembly, which has efficient heat dissipation, is lightweight, has a certain degree of rigidity, and is easy to install.

A photovoltaic assembly includes a photovoltaic module and a heat dissipation module. The heat dissipation module is configured to be connected to an external object. The photovoltaic module includes a light-incident side configured to receive sunlight and a back side opposite to the light-incident side. The photovoltaic module is configured to convert the sunlight to electrical energy. The heat dissipation module is arranged on the back side of the photovoltaic module and configured to dissipate heat generated by the photovoltaic module.

In at least one embodiment, the heat dissipation module includes a heat dissipation structure, the heat dissipation structure includes a honeycomb panel arranged on the back side of the photovoltaic module; the honeycomb panel includes a plurality of honeycomb units, each honeycomb unit extend along a direction from the light-incident side to the back side.

In at least one embodiment, the heat dissipation module further includes a first backplate arranged on a side of the honeycomb panel opposite to the photovoltaic module and configured to be connected to the external object.

In at least one embodiment, the photovoltaic module includes a battery pack, sealing layers arranged two opposite sides of the battery pack, and a junction box electrically connected to the battery pack; the honeycomb panel includes a mounting position arranged on a side of the honeycomb panel facing the photovoltaic module and configured to accommodate the conjunction box.

In at least one embodiment, the photovoltaic module further includes a second backplate, an electrical connector electrically connected to the conjunction box, and a fixing member; the second backplate is arranged on a side of the photovoltaic module facing the honeycomb panel and a side of the second backplate facing the honeycomb panel is the back side; both the conjunction box and the fixing member are arranged on the back side; and the fixing member is configured to fix the electrical connector on the back side.

In at least one embodiment, the honeycomb panel further includes a wiring groove communicated with the mounting position; the wiring groove is arranged on a side of the honeycomb panel facing the second backplate and is configured to receive the fixing member and the electrical connector; the honeycomb panel further includes a mounting groove arranged on the side of the honeycomb panel facing the second backplate and communicated with the wiring groove; the mounting groove is arranged corresponding to the fixing member and is configured to receive the fixing member.

In at least one embodiment, the fixing member is an arc structure having a through hole, the electrical connector is configured to pass through the through hole; the fixing member is elastic; a side of the fixing member opposite to the through hole is provided with grooves facing the honeycomb panel, protrusions protrudes from edges of the mounting groove into the mounting groove; when the honeycomb panel is mounted with the second backplate, the protrusions is capable of being inserted into the grooves.

In at least one embodiment, the photovoltaic assembly further includes a frame, the photovoltaic module and the honeycomb panel are configured to be bonded together to be accommodated in the frame; or the heat dissipation module further includes a frame arranged around the honeycomb panel and configured to be connected to the first backplate to form an accommodating space for accommodating the photovoltaic module.

In at least one embodiment, the honeycomb panel is made of aluminum alloy; a cross-section of the honeycomb panel is one of a regular hexagon, a polygon, a rectangle, a triangle, a rhombus, a circle and an ellipse.

In at least one embodiment, the heat dissipation module includes a heat dissipation structure and a first backplate, the heat dissipation structure includes a corrugated plate arranged on the back side of the photovoltaic module; a side of the corrugated plate adjacent to the photovoltaic module is a first wavy surface, and the first wavy surface includes a plurality of first strip groove having openings at two ends.

In at least one embodiment, a side of the corrugated plate opposite to the photovoltaic module is a second wavy surface, and the second wavy surface includes a plurality of second strip groove having openings at two ends.

In at least one embodiment, a cross-section of the first strip groove is semi-circular; and a cross-section of the second strip groove is semi-circular.

In at least one embodiment, the heat dissipation structure further includes a honeycomb panel arranged on a side of the corrugated plate opposite to the photovoltaic panel; the honeycomb panel includes a plurality of honeycomb units, each honeycomb unit extend along an extension direction of the first strip groove; and a cross-section of the honeycomb panel is one of a regular hexagon, a polygon, a rectangle, a triangle, a rhombus, a circle and an ellipse.

In at least one embodiment, the heat dissipation structure further includes spaced heat dissipation plate, the spaced heat dissipation plate includes two support plates arranged opposite to each other and a plurality of spacer plates arranged perpendicularly between the two support plates, and each two adjacent spacer plates together with the two support plates define a heat dissipation channel in a rectangular or square shape.

In at least one embodiment, the heat dissipation structure further includes spaced heat dissipation plate, the spaced heat dissipation plate includes two support plates arranged opposite to each other and a plurality of spacer plates inclinedly connected between the two support plates, and each two adjacent spacer plates together with the two support plates define a heat dissipation channel in a triangle shape.

In at least one embodiment, the heat dissipation module includes a heat dissipation structure arranged on the backside of the photovoltaic module and a first backplate positioned on a side of the heat dissipation structure that faces away from the photovoltaic module; the first backplate is configured to be connected to the external object; the heat dissipation structure is provided with multiple heat dissipation channels, and the multiple heat dissipation channels extend along a first direction parallel to an extension direction of the photovoltaic module or along a second direction perpendicular to the extension direction of the photovoltaic module.

In at least one embodiment, the photovoltaic assembly further includes a micro-inverter configured to convert direct current outputted by the photovoltaic module to alternate current; and the heat dissipation structure is provided with a cavity area configured to accommodate the micro-inverter.

In at least one embodiment, the photovoltaic assembly further includes an energy storage battery configured to store electrical energy outputted by the photovoltaic module; and the heat dissipation structure is provided with a cavity area configured to accommodate the energy storage battery.

In at least one embodiment, the photovoltaic assembly further includes a control assembly; the control assembly includes a battery management system configured to control charging and discharging of the energy storage battery; and the heat dissipation structure is provided with a cavity area configured to accommodate the control assembly.

In at least one embodiment, the control assembly further includes a maximum power point tracking component configured to dynamically adjust an operating state of the photovoltaic module to ensure that the photovoltaic module keeps outputting a maximum power.

Technical effects of the present disclosure are as follows: comparing with existing technologies, the photovoltaic assembly provided by the present disclosure includes a heat dissipation structure arranged on the back side of the photovoltaic module, enabling rapid dissipation of heat generated by the photovoltaic module, thereby preventing heat transfer to buildings and providing protection to building walls or curtain walls, etc. Meanwhile, by adhering the heat dissipation structure including the honeycomb panel to the backside of the photovoltaic module, the photovoltaic assembly enhances its deformation resistance and increases its stiffness. Moreover, it can be produced in larger sizes and directly installed on buildings or other locations, eliminating the need for steel supports required during photovoltaic assembly installation, thus reducing the weight of the photovoltaic assembly. It can independently serve as a building component, lowering installation costs, expanding the applicability range, and enhancing the practicality of the photovoltaic assembly. Additionally, it allows a combination of a flexible photovoltaic module with the heat dissipation module, which further reduces the weight of the photovoltaic assembly and expands the applicability range of flexible photovoltaic assemblies. The honeycomb panel, made of aluminum alloy, achieves lightweight while ensuring support strength and enhancing corrosion resistance, making the use of the photovoltaic assembly safer. The corrugated panel with first and second strip grooves, positioned between the photovoltaic module and the first backplate, allows the interior of the photovoltaic assembly to form “air ducts” that connect with the exterior, enabling air circulation. This facilitates dissipation of heat generated by the photovoltaic module to the exterior through the “air ducts,” preventing a decrease in power generation due to heat accumulation and avoiding transfer of excess heat to the external objects.

### BRIEF DESCRIPTION OF THE DRAWINGS

FIG. 1 is a schematic diagram of a photovoltaic assembly according to a first embodiment of the present disclosure.

FIG. 2 is a schematic diagram of a photovoltaic assembly from another angle according to the first embodiment of the present disclosure.

FIG. 3 is a schematic diagram of an inner structure of the photovoltaic assembly according to the first embodiment of the present disclosure.

FIG. 4 is a schematic diagram of a photovoltaic module of the photovoltaic assembly in FIG. 1.

FIG. 5 is a structural schematic diagram of a heat dissipation module of the photovoltaic assembly in FIG. 1.

FIG. 6 is a structural schematic diagram of a fixing member in FIG. 4.

FIG. 7 is a cross-sectional view of the fixing member in FIG. 6.

FIG. 8 is schematic diagram of a mounting slot in FIG. 5.

FIG. 9 is a schematic diagram of a photovoltaic assembly according to a second embodiment of the present disclosure.

FIG. 10 is an exploded view of the photovoltaic assembly in FIG. 9.

FIG. 11 is a cross-sectional view of the photovoltaic assembly in FIG. 9.

FIG. 12 illustrate an air flow direction in the photovoltaic assembly in FIG. 9.

FIG. 13 is a cross-sectional view of a corrugated board.

FIG. 14 is a cross-sectional view of another corrugated board.

FIG. 15 is a cross-sectional view of a honeycomb structure.

FIG. 16 is a cross-sectional view of spaced heat dissipation plates.

FIG. 17 is a cross-sectional view of another spaced heat dissipation plates.

FIG. 18 is a schematic view of the photovoltaic assembly including a micro-inverter according to an embodiment of the present disclosure.

FIG. 19 is a schematic view of the photovoltaic assembly including an energy storage battery according to an embodiment of the present disclosure.

FIG. 20 is a schematic view of the photovoltaic assembly including a control assembly according to an embodiment of the present disclosure.

FIG. 21 is a schematic view of the photovoltaic assembly including the micro-inverter, the energy storage battery, and the control assembly according to an embodiment of the present disclosure.

FIG. 22 is a schematic view of the photovoltaic assembly including the micro-inverter, the energy storage battery, and the control assembly according to another embodiment of the present disclosure.

FIG. 23 is a schematic view of the photovoltaic assembly including the micro-inverter, the energy storage battery according to an embodiment of the present disclosure.

### DETAILED DESCRIPTION

To make objectives, technical solutions, and advantages of the present disclosure clearer, the present disclosure will be further described in detail below with reference to accompanying drawings and specific embodiments. It should be understood that specific embodiments described herein are merely illustrative of the present disclosure and are not intended to limit the present disclosure.

To make the description of the present disclosure more detailed and complete, illustrative descriptions of the embodiments and specific examples of the present disclosure are provided below; however, this is not the only form of implementing or applying the specific examples of the present disclosure. The implementation methods cover features of multiple specific embodiments and the methods, steps, and their order for constructing and operating these specific embodiments. However, other specific embodiments can also be configured to achieve the same or equivalent functions and steps. Based on the embodiments in this application, all other embodiments obtained by those skilled in the art without creative effort are within the scope of protection of this application.

It should be noted that when a component is referred to as “fixed to” or “arranged on” another component, it can be directly arranged on said another component or indirectly arranged on said other component. When a component is referred to be “connected to” another component, it can be directly connected to said another component or indirectly connected to said another component.

It should be understood that the terms “first,” “second,” etc., in the specification, claims, and accompanying drawings of the present disclosure are configured to distinguish similar objects and are not necessarily configured to describe a specific order or sequence. It should be understood that the data used in this way can be interchanged where appropriate so that the embodiments of the present disclosure described herein can be implemented in a sequence other than those illustrated or described herein.

In the description of the present disclosure, the terms “front,” “rear,” “top,” “inner,” and “outer,” etc., indicate the orientation or positional relationship based on the orientation or positional relationship shown in the accompanying drawings. They are used only for the convenience of describing the present disclosure and simplifying the description, and do not indicate or imply that the device or element referred to must have a specific orientation, or be constructed and operated in a specific orientation. Therefore, they should not be construed as limitations on the present disclosure.

### Embodiment I

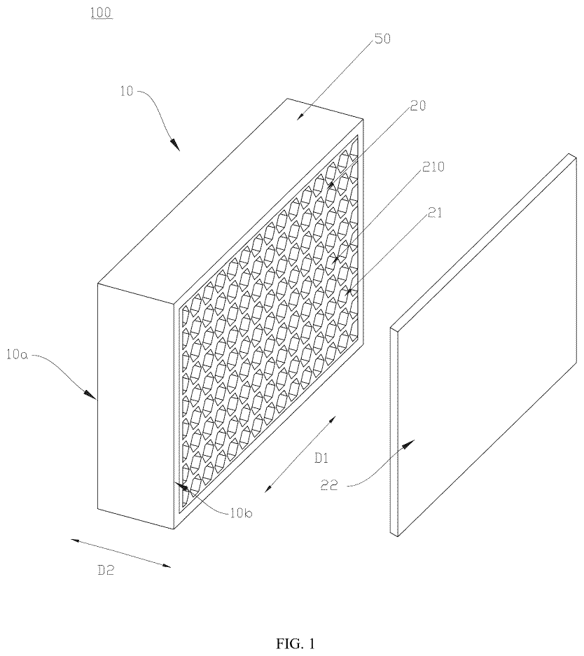

Please referring to FIG. 1, which is a perspective view of a lightweight and efficient heat dissipation photovoltaic assembly 100 provided in a first embodiment of the present disclosure.

The photovoltaic assembly 100 provided in this embodiment includes: a photovoltaic module 10 and a heat dissipation module configured to be connected to an external object. The photovoltaic module 10 includes a light-incident side 10a and a back side 10b located on an opposite side of the light-incident side 10a. The light-incident side 10a is configured to receive light energy, and the photovoltaic module 10 is configured to receive light energy and convert received light energy into electrical energy. The heat dissipation module is arranged on the back side 10b side of the photovoltaic module 10.

Compared with the existing technologies, the photovoltaic assembly 100 provided by the present disclosure adopts a heat dissipation module arranged on the back side 10b of the photovoltaic module 10, so that heat generated by the photovoltaic module 10 cannot be transferred to the building, which has a protective effect on building walls or curtain walls, and further provides support for the photovoltaic module 10.

In some embodiments, the heat dissipation module is provided with multiple heat dissipation channels configured to facilitate heat dissipation out from the photovoltaic module 10. In some embodiments, the heat dissipation channels may extend along a first direction D1 in which the photovoltaic module 10 extends. In other embodiments. In other embodiments, the heat dissipation channels may extend along a second direction D2 perpendicular to an extension direction of the photovoltaic module 10.

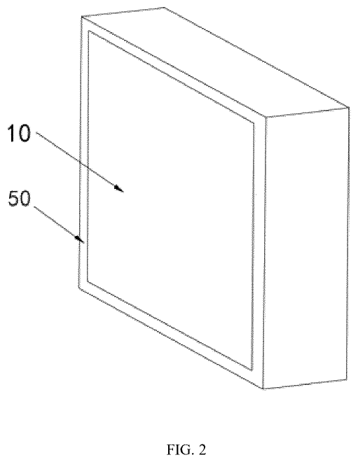

Referring to FIGS. 1, 2 and 3, in the first embodiment, the heat dissipation module includes a honeycomb panel 20, which is arranged on the back side 10b of the photovoltaic module 10. The honeycomb panel 20 includes a plurality of honeycomb units 21, each of which extends along the extension direction from the light-incident side 10a to the back side 10b. Each honeycomb unit 21 defines a heat dissipation channel 210.

In this embodiment, the photovoltaic assembly 100 further includes a frame 50. The photovoltaic module 10 and the heat dissipation module (the honeycomb panel 20) are connected by an adhesive layer 60 and then fitted inside the frame 50.

Specifically, the adhesive layer 60 is an epoxy resin adhesive or a polyurethane adhesive.

By using epoxy resin or polyurethane adhesives, which have good thermal conductivity, insulation, and high temperature resistance, the adhesive layer 60 can accelerate the heat dissipation of the photovoltaic module 10 and thereby improves the photoelectric conversion efficiency of the photovoltaic module 10.

Of course, the photovoltaic module 10 can be connected to the honeycomb panel 20 in other ways, such as screw fixing or snap-fit connection, or other methods that can achieve a connection between the photovoltaic module 10 and the heat dissipation module.

In this embodiment, the photovoltaic module 10 is connected to the honeycomb panel 20 and then installed in the frame 50.

At this time, an orthographic projection of the honeycomb panel 20 covers an orthographic projection of the photovoltaic module 10.

In other embodiments, the frame 50 can be connected to the honeycomb panel 20 before the photovoltaic module 10 is installed inside.

That is, the frame 50 is connected to the honeycomb panel 20 to form a storage space for storing the photovoltaic module 10.

In this embodiment, the honeycomb panel 20 and the frame 50 can be integrally formed, or a storage space for the photovoltaic module 10 can be cut out from a whole piece of a honeycomb panel material, and then the photovoltaic module 10 can be installed into it.

The use of the honeycomb panel 20 with the honeycomb units 21 on the back side 10b of the photovoltaic module 10 improves deformation resistance and rigidity of the photovoltaic assembly 100. Furthermore, it allows for production of photovoltaic assemblies in larger sizes and direct installation of photovoltaic assemblies in buildings, eliminating the need for steel supports during installation and reducing the weight of the photovoltaic assembly 100. This allows the photovoltaic assembly to function as an independent building component applied on the building, lowering installation costs, expanding its applicability, and enhancing its practicality.

Specifically, in the first embodiment, the heat dissipation module further includes a first backplate 22, which is arranged on a side of the honeycomb panel 20 away from the photovoltaic module 10 and is configured to connect with an external object.

The first backplate 22 can effectively protect the honeycomb panel 20, prevent wear and tear on the honeycomb panel 20, thus prolonging the service life of the honeycomb panel 20. In some embodiments, the first backplate 22 can be a metal plate with high hardness and good heat dissipation performance, such as, an aluminum plate, an iron plate, a steel plate, an aluminum alloy plate, etc.,

In the embodiment of the present disclosure, the photovoltaic module 10 can be a monocrystalline silicon solar panel, a polycrystalline silicon solar panel, a thin-film solar panel, or other types of solar panels; the present disclosure does not impose any limitations.

To facilitate understanding of the technical points of the present disclosure, the present disclosure describes part of the structure of the photovoltaic module 10, but this does not mean that the photovoltaic module 10 has only this part of the structure or that this part of the structure is essential.

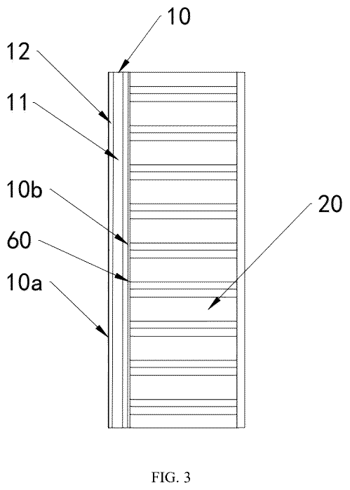

Please referring to FIG. 3, In the embodiment, the photovoltaic module 10 includes a battery pack 11, a sealing layer 12 arranged on upper and lower surfaces of the battery pack 11, and a junction box 13 electrically connected to the battery pack 11. The sealing layer 12 can specifically be a polymer layer. By configuring the sealing layer 12 to encapsulate the battery pack 11, it not only protects the battery pack 11 but also provides shockproof, moisture-proof, waterproof, and insulating effects. This allows the photovoltaic assembly 100 to be well-suited for different weather conditions when used outdoors, avoiding impact due to outdoor weather changes and improving the user experience.

Since improvements of the present disclosure are mainly aimed at achieving the lightweighting of the photovoltaic assembly 100 while maintaining the rigidity required by building structures, the improvements are primarily focused on the specific structure of the photovoltaic assembly 100 and do not involve improvements to the circuit chips in the photovoltaic assembly 100. Therefore, specific circuit chips, etc., will not be described in detail.

To better protect the photovoltaic module 10, an encapsulation layer (not shown in the drawings) may be provided on an outside of the light-incident side 10a of the photovoltaic module 10. The encapsulation layer includes a transmission layer and a reflection layer, with the transmission layer located above the reflection layer.

This encapsulation layer is not a protective layer 17 used in the prior art to protect the battery pack 11 from corrosion, but a structure configured to improve the photoelectric conversion efficiency of the battery pack 11. The encapsulation layer includes a transmission layer and a reflection layer. The reflection layer is located above the irradiated surface of the polycrystalline silicon chip, and the transmission layer is located above the reflection layer. The transmission layer has the ability to transmit sunlight and to reflect infrared rays, that is, to transmit visible light from 320 to 1100 nm and reflect infrared rays. When visible light is irradiated on the surface of the battery pack 11, some of the light will be reflected or refracted, and only a small portion of the light will participate in photoelectric conversion. The reflection layer can reflect some of the sunlight reflected back from the irradiated surface of the battery pack 11 back to the irradiated surface of the battery pack 11 to continue photoelectric conversion.

Furthermore, the transmissive layer transmits sunlight and reflects infrared rays; the reflective layer reflects a portion of the sunlight reflected back by the light-incident side 10a back to the light-incident side 10a.

By configuring the transmission layer to transmit sunlight and reflect infrared rays, the reflection layer reflects some of the sunlight reflected back by the light-incident side 10a back to the light-incident side 10a. This not only reduces the interference of infrared rays on the battery pack 11, but also “retains” more photons reflected back by the light-incident side 10a through reflection, allowing them to continue to participate in the photoelectric conversion of the battery pack 11, thereby effectively improving the photoelectric conversion efficiency of the battery pack 11.

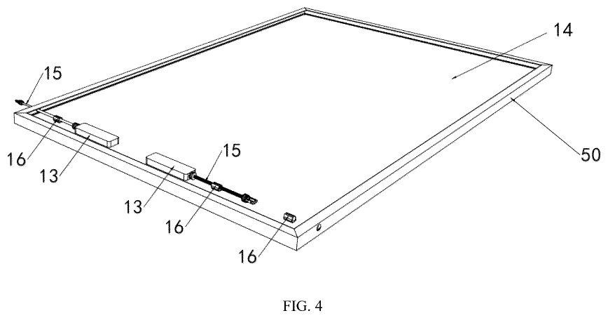

Please referring to FIG. 4, the honeycomb panel 20 further includes a mounting position 23, which is located on a side of the honeycomb panel 20 facing the photovoltaic module 10 and is configured to house the junction box 13.

The mounting position 23 is configured to house the junction box 13, which allows the junction box 13 to be hidden between the photovoltaic module 10 and the honeycomb panel 20. This makes the overall appearance of the photovoltaic assembly more aesthetically pleasing and neat. It further provides protection for the junction box 13 and an electrical connector 15, thereby prolonging their service life and reducing malfunctions.

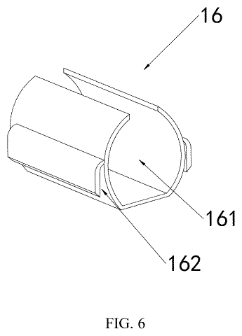

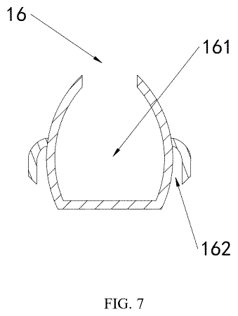

Please referring to FIGS. 4, 6, and 7, the photovoltaic module 10 further includes a second backplate 14, the electrical connector 15 electrically connected to the junction box 13, and a fixing member 16. The second backplate 14 is located on a side of the photovoltaic module 10 facing the honeycomb panel 20, and the side of the second backplate 14 facing the honeycomb panel 20 is the back side 10b. The junction box 13 and the fixing member 16 are both located on the back side 10b of the second backplate 14. The fixing member 16 is configured to keep the electrical connector 15 on the back side 10b of the second backplate 14.

The fixing member 16 can fix the electrical connector 15 on the second backplate 14, making the layout of the electrical connector 15 neater and more aesthetically pleasing, and further facilitating assembly.

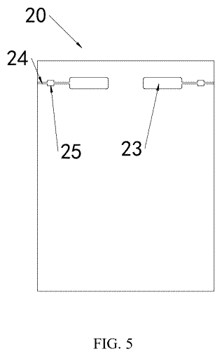

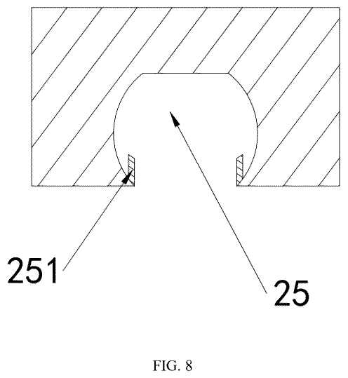

Please referring to FIGS. 5 and 8, the honeycomb panel 20 further includes a wiring groove 24 communicating with the mounting position 23. The wiring groove 24 is located on the side of the honeycomb panel 20 facing the second backplate 14 and is configured to accommodate the fixing member 16 and the electrical connector 15. The honeycomb panel 20 further includes a mounting groove 25. The mounting groove 25 is located on the side of the honeycomb panel 20 facing the second backplate 14 and communicates with the wiring groove 24. The mounting groove 25 is arranged corresponding to the fixing member 16 to accommodate the fixing member 16.

The mounting position 23, the wiring groove 24, and the mounting groove 25 are provided so that when the honeycomb panel 20 is located on the back side 10b of the photovoltaic module 10, there is enough space to accommodate the junction box 13, the fixing member 16, and the electrical connector 15, thus avoiding damage to the junction box 13 and the like during assembly.

Of course, in other embodiments, the mounting position 23, the wiring groove 24 and the mounting groove 25 can be grooves of similar width, which can accommodate the junction box 13, the electrical connector 15 and the fixing member 16 respectively.

In another embodiment, the photovoltaic module 10 may not have the second backplate 14, and the honeycomb panel 20 may be used as the second backplate. The junction box 13, the fastener 16 and the wiring groove 24 are all located on the back side of the honeycomb panel 20, such as being directly installed on the surface of the back side of the honeycomb panel 20 or installed in grooves defined on the back side of the honeycomb panel 20.

Specifically, the fixing member 16 is an arc-shaped structure with a through hole 161. The electrical connector 15 is configured to passes through the through hole 161, and the fixing member 16 has a certain elasticity. A side of the fixing member 16 away from the through hole 161 is provided with a groove 162 with an opening facing the first backplate 22, and an edge of the mounting groove 25 is provided with a protrusion 251 configured to protrude into the mounting groove 25. When the honeycomb panel 20 is installed on the second backplate 14, the protrusion 251 is inserted into the groove 162. The fastener 16 has a certain degree of elasticity, which allows the protrusion 251 on the mounting groove 25 to be smoothly inserted into the groove 162, thereby achieving engagement of the protrusion 251 and the groove 162 to connect the honeycomb panel 20 and the photovoltaic module 10, thus preventing them from separating.

Meanwhile, to make installation smoother, the groove 162 and the protrusion 251 can be provided with inclined surfaces as guide surfaces. After installation, the inclined surface on the groove 162 and the inclined surface on the protrusion 251 are opposite to each other, making it difficult for them to separate. In this embodiment, the protrusion 251 has a certain elasticity and can undergo slight deformation so that it can be smoothly inserted into the groove 162. Of course, in the embodiment, there are other ways to connect the photovoltaic module 10 and the honeycomb panel 20 to ensure a stable connection between them.

To facilitate connections of multiple photovoltaic assemblies 100 and enable their array arrangement, holes or slots can be made through the frame 50 to allow the electrical connector 15 to be arranged therein, thereby enabling an electrical connection with adjacent photovoltaic assemblies 100.

In this embodiment, multiple photovoltaic modules 100 can be arranged and combined; or the heat dissipation module can be made larger, and then the photovoltaic modules 10 can be arranged and combined within it to facilitate application to various scenarios with different needs. This application does not impose any restrictions. In this way, the photovoltaic assembly 100 can have good deformation resistance, increased rigidity, improved deformation resistance, can be produced in larger sizes, reduce the weight of the photovoltaic module 10, can be used as an independent building component, save installation costs, expand the application range of the photovoltaic module 10, and improve the practicality of the lightweight and efficient heat dissipation photovoltaic assembly 100.

To ensure overall product weight reduction while maintaining structural strength and corrosion resistance, the honeycomb panel 20 in this embodiment is made of aluminum alloy; the cross-section of the honeycomb unit 21 is any one of hexagonal, polygonal, rectangular, triangular, rhomboid, circular, and elliptical.

It can be understood that, in other embodiments, the honeycomb unit 21 can be other structural forms. The honeycomb unit 21 can be a solid structure or a hollow structure. This application does not impose any restrictions, as long as the support strength can be ensured.

### Embodiment II

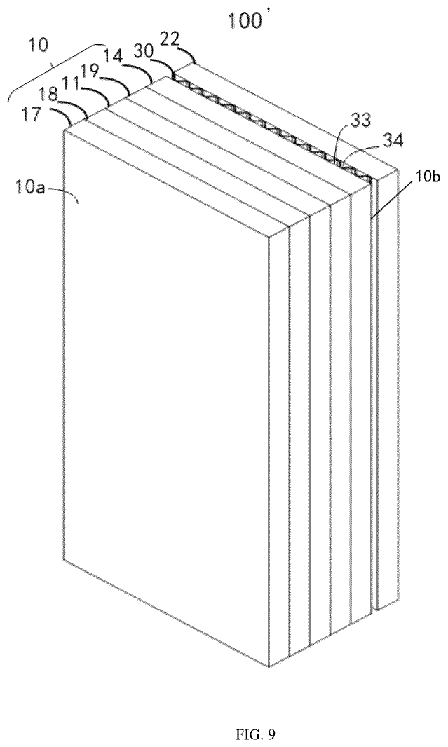

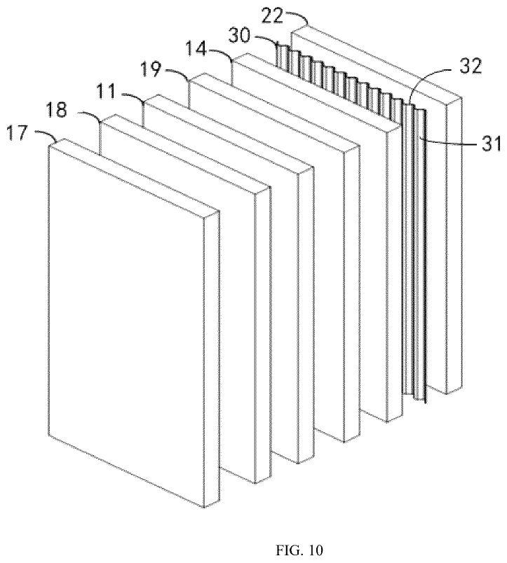

Please refer to FIGS. 9 to 12, a second embodiment of the present disclosure provides another lightweight and efficient heat dissipation photovoltaic assembly 100′, including a photovoltaic module 10 and a heat dissipation module. The heat dissipation module includes a heat dissipation structure and a first backplate 22. The heat dissipation structure includes a corrugated plate 30. The photovoltaic module 10 is configured to receive light energy and convert it into electrical energy. It includes a light-incident side 10a and a back side 10b located on the opposite side of the light-incident side 10a. The corrugated plate 30 is arranged on the back side 10b of the photovoltaic module 10 and is bonded to the back side 10b through a first adhesive layer (not shown). The first backplate 22 is arranged on a side of the corrugated plate 30 away from the back side 10b and is bonded to the first backplate 22 through a second adhesive layer (not shown). The first backplate 22 is configured to mount the photovoltaic module 10 on an external object. The surface of the corrugated plate 30 adjacent to the first adhesive layer has a plurality of first strip grooves 33 with openings at both ends and/or the side of the corrugated plate 30 adjacent to the second adhesive layer has a plurality of second strip grooves 34 with openings at both ends. In this embodiment, the corrugated plate 30 has a plurality of first strip grooves 33 with openings at both ends on the surface adjacent to the first adhesive layer, and the corrugated plate 30 has a plurality of second strip grooves 34 with openings at both ends on the side adjacent to the second adhesive layer. The first strip grooves 33 and the second strip grooves 34 extends along the extension direction of the photovoltaic module 10 to form the heat dissipation channels.

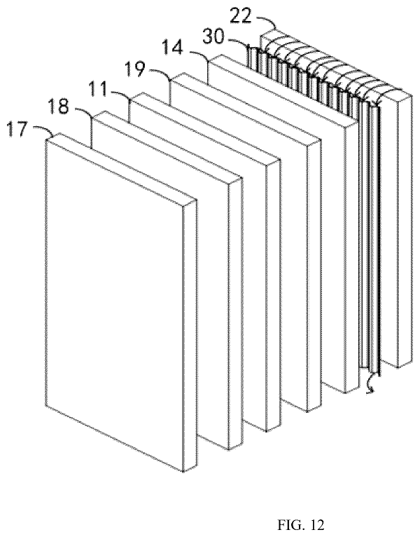

It is understood that the photovoltaic assembly 100′ provided by the present disclosure, by configuring the corrugated plate 30 between the photovoltaic module 10 and the first backplate 22, and the corrugated plate 30 having a plurality of first strip grooves 33 with openings at both ends on the surface adjacent to the photovoltaic module 10 and/or the corrugated plate 30 having a plurality of second strip grooves 34 with openings at both ends on the side adjacent to the first backplate 22, can form an “air duct” inside the photovoltaic assembly 100′ and have the air duct connected to the outside of the photovoltaic assembly 100′. Therefore, the air inside and outside the photovoltaic assembly 100′ can circulate, thereby carrying away the heat generated by the heat dissipation photovoltaic assembly 100 through the convection of the “air duct” formed by the corrugated plate 30, as shown by the arrow direction in FIG. 12. It can avoid decrease in power generation of the photovoltaic assembly 100′ caused by heat accumulation, and at the same time avoiding the transfer of excess heat to external objects. In addition, the photovoltaic module 10 can be made into patterns such as stone, brick, and tile, which can make it more aesthetically pleasing when installed on external objects, such as outside buildings.

Specifically, the surface of the corrugated plate 30 adjacent to the first adhesive layer is a first wavy surface 31, thereby forming the plurality of first strip grooves 33 with openings at both ends. It is understood that the corrugated plate 30 can be an aluminum corrugated core plate, which is formed into various waveforms by rolling and cold bending of an aluminum plate through a whole plate pressing mold. The processing method is simple, mass production is possible, and the production cost is low. At the same time, since it is formed as a whole plate, there is no need for welding or other connection between the multiple first strip grooves 33, which ensures integrity of the corrugated plate 30. No air leakage will occur in the entire first strip groove 33 due to welding or other connection methods, so that the corrugated plate 30 forms the “air duct” with higher air guiding efficiency.

In this embodiment, the surface of the corrugated plate 30 adjacent to the second adhesive layer is a second wavy surface 32, thereby forming the plurality of second strip grooves 34 with openings at both ends. It is understood that the corrugated plate 30 can be an aluminum corrugated core plate, which is formed into various waveforms by rolling and cold bending of aluminum plate through a whole plate pressing mold. The processing method is simple, mass production is possible, and the production cost is low. At the same time, since it is formed as a whole plate, there is no need for welding or other connection between the multiple second strip grooves 34, which ensures the integrity of the corrugated plate 30. There will be no air leakage in the entire second strip groove 34 due to welding or other connection methods, so that the corrugated plate 30 forms the “air duct” with higher air guiding efficiency.

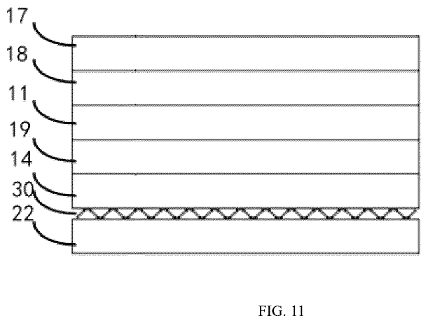

It should be noted that the corrugated plate 30 can be formed by roll forming, pressing the surface of the corrugated plate 30 adjacent to the first adhesive layer into the first wavy surface 31, or pressing the surface of the corrugated plate 30 adjacent to the second adhesive layer into the second wavy surface 32, or simultaneously pressing the surface of the corrugated plate 30 adjacent to the first adhesive layer into the first wavy surface 31 and the surface of the corrugated plate 30 adjacent to the second adhesive layer into the second wavy surface 32. In this embodiment, the surface of the corrugated plate 30 adjacent to the first adhesive layer is the first wavy surface 31 and the surface adjacent to the second adhesive layer is the second wavy surface 32, as shown in FIG. 11. It can be formed in one step by pressing the whole sheet without additional processing. At the same time, the corrugated plate 30 has both the first strip groove 33 and the second strip groove 34 on both sides, which can improve heat dissipation efficiency and thus improve cooling efficiency.

In addition, the corrugated plate 30 can be an aluminum corrugated core plate, which has thermal conductivity and can further improve heat dissipation efficiency. In other embodiments, the corrugated plate 30 may also be a material that has both fire resistance and thermal conductivity, such as aluminum, iron or other non-metallic materials, or other materials that have fire resistance or thermal conductivity.

Furthermore, the photovoltaic module 10 includes a protective layer 17, a first encapsulant film 18, a battery pack 11, a second encapsulant film 19, and a second backplate 14 arranged sequentially along the light-incident side 10a to the back side 10b, wherein the surface of the second backplate 14 adjacent to the corrugated plate 30 is the back side 10b of the photovoltaic module 10. The protective layer 17 is a photovoltaic protective layer, which can be made of glass or other transparent materials. The first adhesive film 18 and the second adhesive film 19 are ethylene-vinyl acetate copolymer (EVA) or polyvinyl butyral (PVB). The battery pack 11 is a conductive copper strip battery cell, and the second backplate 14 is a solar back sheet (TPT) that protects and supports the battery pack 11.

By configuring the photovoltaic module 10 with the protective layer 17, the first encapsulant film 18, the battery pack 11, the second encapsulant film 19, and the second backplate 14 sequentially along the light-incident side 10a to the back side 10b, the photovoltaic module 10 can convert light energy into electrical energy for use by other devices under sunlight, thus saving energy. It is understood that in other embodiments, the photovoltaic module 10 may not have the protective layer 17 or the second backplate 14, and the corrugated plate 30 may be used directly as the second backplate 14. Furthermore, since the improvements of the present disclosure are mainly aimed at achieving the lightweighting of the photovoltaic assembly 100′ while maintaining the rigidity required by building structures, the improvements are primarily focused on the specific structure of the photovoltaic assembly 100′ and do not involve improvements to the circuitry and electrical connectors 15 within the photovoltaic assembly 100′. Therefore, the circuitry and the electrical connectors 15 will not be described. The structure of the photovoltaic assembly 100′ can also refer to the structure of the photovoltaic assembly 100 in Embodiment I, and this application does not impose any limitations.

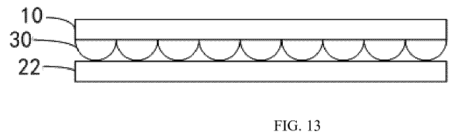

Specifically, as shown in FIG. 13, the cross-section of the first strip groove 33 is semi-circular. Of course, in other embodiments, the cross-section of the first strip groove 33 may be of other shapes.

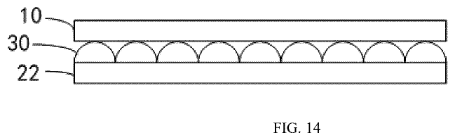

Please referring to FIG. 14, the cross-section of the second strip groove 34 is semi-circular. Of course, in other embodiments, the cross-section of the second strip groove 34 may also be of other shapes.

It should be noted that the corrugated plate 30 may have the first strip groove 33 with the semi-circular cross-section, as shown in FIG. 13, or the second strip groove 34 with the semi-circular cross-section, as shown in FIG. 14. It may have both the first strip groove 33 with the semi-circular cross-section and the second strip groove 34 with the semi-circular cross-section.

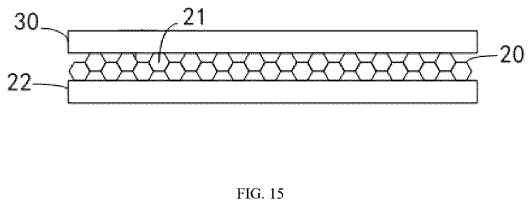

Please referring to FIG. 15, in order to further reduce the impact of the heat generated by the photovoltaic module 10 on the power generation efficiency and the external objects, such as buildings, in this embodiment, the heat dissipation structure further includes a honeycomb panel 20, which is arranged between the corrugated plate 30 and the first backplate 22. By configuring the honeycomb panel 20, excess heat from the photovoltaic assembly 100 can be prevented from being transferred to external objects.

In this embodiment, the honeycomb panel 20 includes a plurality of honeycomb units 21, each of which extends along the extending direction of the first strip groove 33, and the cross-section of the honeycomb unit 21 is any one of regular hexagon, polygon, rectangle, triangle, rhombus, circle and ellipse. The heat dissipation efficiency can be improved by configuring the heat dissipation structure as the honeycomb cell 21 with the regular hexagonal cross-section.

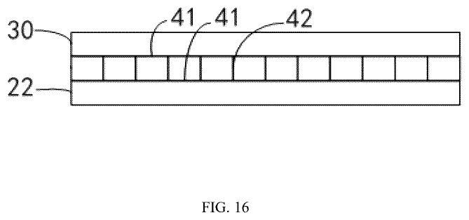

In some other embodiments, please referring to FIG. 16, the heat dissipation structure includes spaced heat dissipation plates 40, which includes two support plates 41 arranged opposite to each other and a plurality of spacer plates 42 vertically connected between the two support plates 41. The two adjacent spacer plates 42 and the two support plates 41 form the heat dissipation channels with a rectangular or square cross section. By configuring the heat dissipation structure into the heat dissipation channels with the rectangular or the square cross-section, the heat dissipation efficiency can be improved.

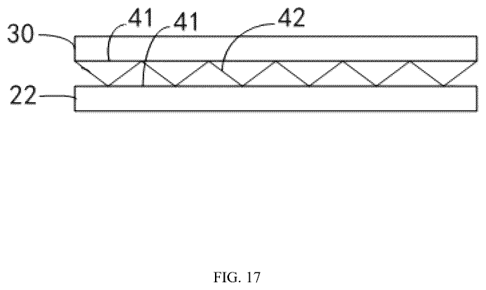

In some other embodiments, please referring to FIG. 17, the spaced heat dissipation plates 40 include two support plates 41 arranged opposite to each other and a plurality of spacer plates 42 inclinedly connected between the two support plates 41. The two adjacent spacer plates 42 and the two support plates 41 form the heat dissipation channels with an equilateral triangle cross section. By configuring the heat dissipation structure as the heat dissipation channels with an equilateral triangular cross-section, the heat dissipation efficiency can be improved.

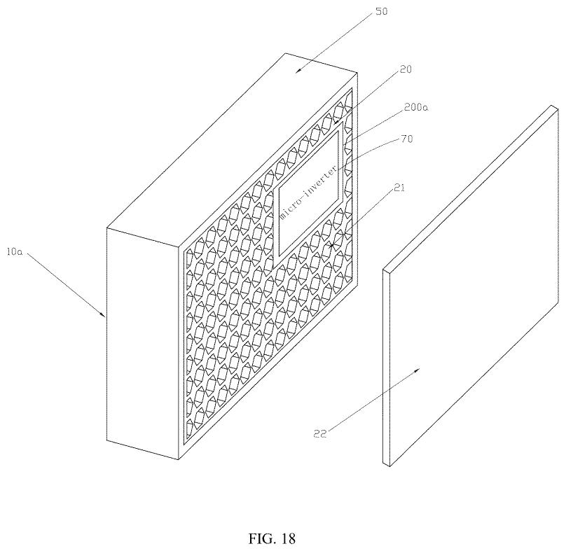

In some embodiments, as shown in FIG. 18, the photovoltaic assembly 100/100′ further includes a micro-inverter 70 configured to convert a low-voltage direct current (DC) output (e.g., 20-50V) from the photovoltaic module 10 into alternating current (AC) (e.g., 220V/380V). In some embodiments, the micro-inverter 70 is configured with Maximum Power Point Tracking (MPPT) functionality. A first cavity area 200a is provided within the heat dissipation structure to accommodate the micro-inverter 70.

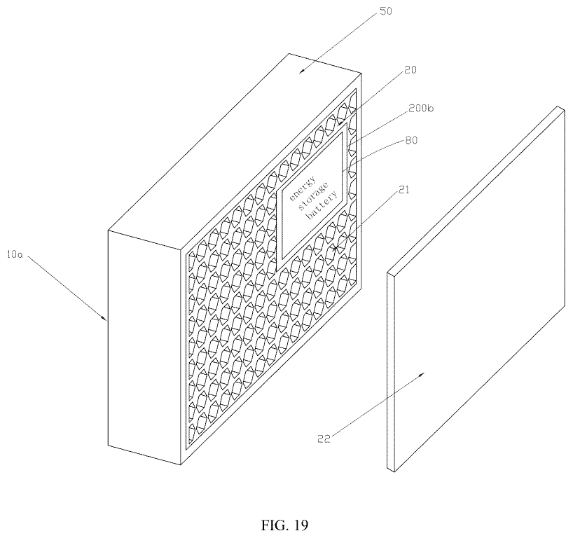

As an embodiment, as shown in FIG. 19, the photovoltaic module 100 further includes an energy storage battery 80 configured to store the electrical energy output by the photovoltaic module 10. A second cavity area 200b is provided within the heat dissipation structure to house the energy storage battery 80.

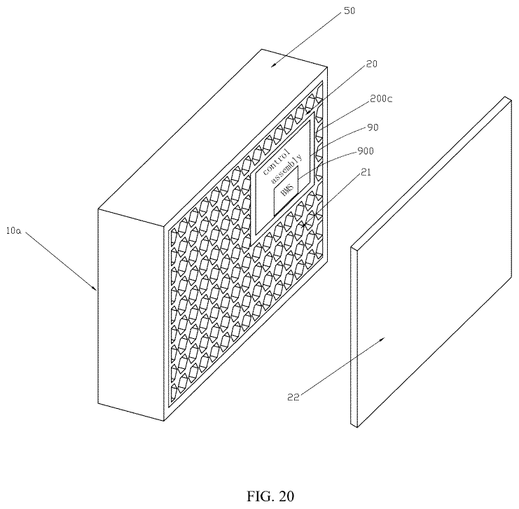

As an embodiment, as shown in FIG. 20, the photovoltaic module 100 further includes a control assembly 90, which includes, but is not limited to, a Battery Management System (BMS) 900. A third cavity area 200c is provided within the heat dissipation structure to accommodate the control assembly 90.

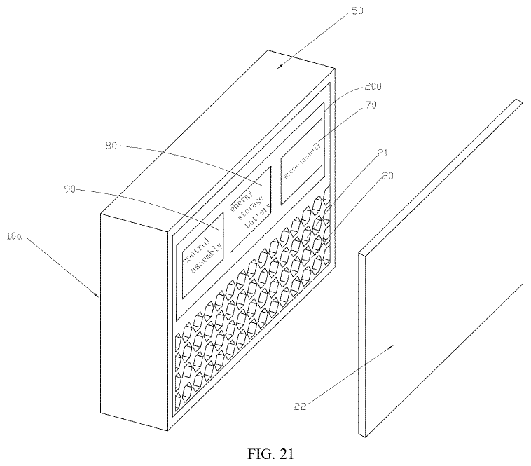

In some embodiments, as shown in FIG. 21, the micro-inverter 70, the energy storage battery 80, and the control assembly 90 can be placed within a single cavity area 200.

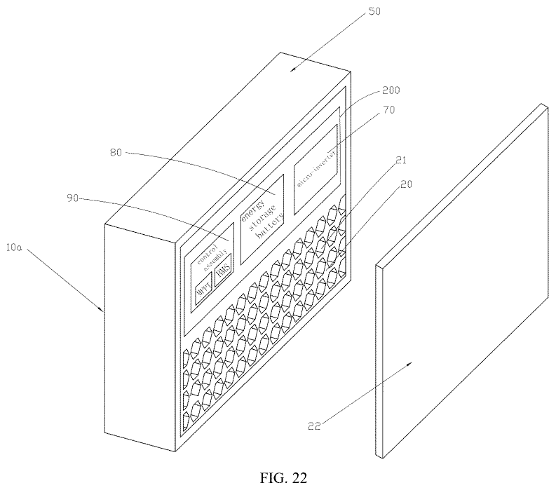

In some embodiments, as shown in FIG. 22, the MPPT and BMS are integrated into a single control assembly. The micro-inverter 70, the energy storage battery 80, and the control assembly 90 can be placed either within a single cavity area or in separate corresponding cavity areas.

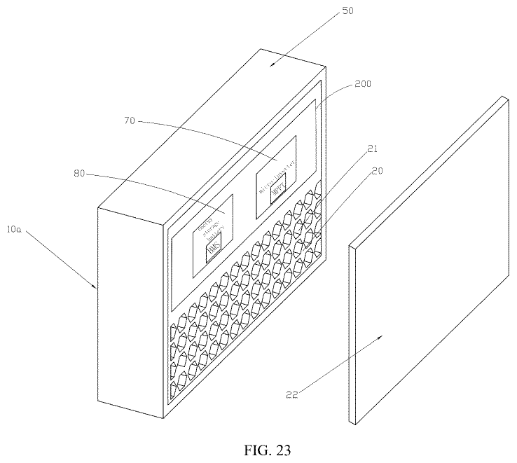

In some embodiments, as shown in FIG. 23, the micro-inverter 70 is configured with built-in MPPT functionality, and the energy storage battery 80 is configured with built-in BMS functionality. The micro-inverter 70 and the energy storage battery 80 can either be placed separately within different cavity areas or together within a single cavity area.

The aforementioned cavity areas can be located within the honeycomb panel 20 or the spaced heat dissipation plates 40. The remaining areas within the honeycomb panel 20 or the spaced heat dissipation plates 40, outside the cavity areas, are non-cavity regions with honeycomb structures or heat dissipation spaces.

In some implementations, a thickness of the micro-inverter 70 in the first direction D1 is less than that of the heat dissipation structure; a thickness of the energy storage battery 80 in the first direction D1 is less than that of the heat dissipation structure; and a thickness of the control assembly 90 in the first direction D1 is less than that of the heat dissipation structure in the same direction. This not only allows the heat dissipation structure to more effectively protect the micro-inverter 70, the energy storage battery 80, and the control assembly 90 but also ensures the flatness of the photovoltaic assembly.

In some implementations, the micro-inverter 70, the energy storage battery 80, and the control assembly 90 are fixedly placed within the cavity areas through methods such as adhesive bonding or snap-fitting. To ensure insulation performance, the adhesive used for bonding can be an insulating adhesive. For example, the adhesive can be, but is not limited to, insulating adhesives such as silicone rubber, epoxy resin, or polyurethane adhesive.

The above embodiments only illustrate preferred embodiments of the present disclosure, and their descriptions are relatively specific and detailed, but they should not be construed as limiting the scope of the present disclosure patent.

It should be noted that those skilled in the art can make various modifications and improvements without departing from the concept of the present disclosure, and these modifications and improvements are all within the scope of protection of the present disclosure.

Therefore, the scope of protection of the present disclosure patent shall be determined by appended claims.

What is claimed is:

1. A photovoltaic assembly, comprising:
a photovoltaic module; and
a heat dissipation module, configured to be connected to an external object;
wherein the photovoltaic module comprises a light-incident side configured to receive sunlight and a back side opposite to the light-incident side, the photovoltaic module is configured to convert the sunlight to electrical energy, and the heat dissipation module is arranged on the back side of the photovoltaic module and configured to dissipate heat generated by the photovoltaic module.

2. The photovoltaic assembly according to claim 1, wherein the heat dissipation module comprises a heat dissipation structure, the heat dissipation structure comprises a honeycomb panel arranged on the back side of the photovoltaic module; the honeycomb panel comprises a plurality of honeycomb units, each honeycomb unit extend along a direction from the light-incident side to the back side.

3. The photovoltaic assembly according to claim 2, wherein the heat dissipation module further comprises a first backplate arranged on a side of the honeycomb panel opposite to the photovoltaic module and configured to be connected to the external object.

4. The photovoltaic assembly according to claim 3, wherein the photovoltaic module comprises a battery pack, sealing layers arranged two opposite sides of the battery pack, and a junction box electrically connected to the battery pack; the honeycomb panel comprises a mounting position arranged on a side of the honeycomb panel facing the photovoltaic module and configured to accommodate the conjunction box.

5. The photovoltaic assembly according to claim 4, wherein the photovoltaic module further comprises a second backplate, an electrical connector electrically connected to the conjunction box, and a fixing member; the second backplate is arranged on a side of the photovoltaic module facing the honeycomb panel and a side of the second backplate facing the honeycomb panel is the back side; both the conjunction box and the fixing member are arranged on the back side; and the fixing member is configured to fix the electrical connector on the back side.

6. The photovoltaic assembly according to claim 5, wherein the honeycomb panel further comprises a wiring groove communicated with the mounting position; the wiring groove is arranged on a side of the honeycomb panel facing the second backplate and is configured to receive the fixing member and the electrical connector; the honeycomb panel further comprises a mounting groove arranged on the side of the honeycomb panel facing the second backplate and communicated with the wiring groove; the mounting groove is arranged corresponding to the fixing member and is configured to receive the fixing member.

7. The photovoltaic assembly according to claim 6, wherein the fixing member is an arc structure having a through hole, the electrical connector is configured to pass through the through hole; the fixing member is elastic; a side of the fixing member opposite to the through hole is provided with grooves facing the honeycomb panel, protrusions protrudes from edges of the mounting groove into the mounting groove; when the honeycomb panel is mounted with the second backplate, the protrusions is capable of being inserted into the grooves.

8. The photovoltaic assembly according to claim 3, further comprising a frame, the photovoltaic module and the honeycomb panel are configured to be bonded together to be accommodated in the frame; or
the heat dissipation module further comprises a frame arranged around the honeycomb panel and configured to be connected to the first backplate to form an accommodating space for accommodating the photovoltaic module.

9. The photovoltaic assembly according to claim 2, wherein the honeycomb panel is made of aluminum alloy; a cross-section of the honeycomb panel is one of a regular hexagon, a polygon, a rectangle, a triangle, a rhombus, a circle and an ellipse.

10. The photovoltaic assembly according to claim 1, wherein the heat dissipation module comprises a heat dissipation structure and a first backplate, the heat dissipation structure comprises a corrugated plate arranged on the back side of the photovoltaic module; a side of the corrugated plate adjacent to the photovoltaic module is a first wavy surface, and the first wavy surface comprises a plurality of first strip groove having openings at two ends.

11. The photovoltaic assembly according to claim 10, wherein a side of the corrugated plate opposite to the photovoltaic module is a second wavy surface, and the second wavy surface comprises a plurality of second strip groove having openings at two ends.

12. The photovoltaic assembly according to claim 11, wherein a cross-section of the first strip groove is semi-circular; and a cross-section of the second strip groove is semi-circular.

13. The photovoltaic assembly according to claim 10, wherein the heat dissipation structure further comprises a honeycomb panel arranged on a side of the corrugated plate opposite to the photovoltaic panel; the honeycomb panel comprises a plurality of honeycomb units, each honeycomb unit extend along an extension direction of the first strip groove; and a cross-section of the honeycomb panel is one of a regular hexagon, a polygon, a rectangle, a triangle, a rhombus, a circle and an ellipse.

14. The photovoltaic assembly according to claim 10, wherein the heat dissipation structure further comprises spaced heat dissipation plate, the spaced heat dissipation plate comprises two support plates arranged opposite to each other and a plurality of spacer plates arranged perpendicularly between the two support plates, and each two adjacent spacer plates together with the two support plates define a heat dissipation channel in a rectangular or square shape.

15. The photovoltaic assembly according to claim 1, wherein the heat dissipation structure further comprises spaced heat dissipation plate, the spaced heat dissipation plate comprises two support plates arranged opposite to each other and a plurality of spacer plates inclinedly connected between the two support plates, and each two adjacent spacer plates together with the two support plates define a heat dissipation channel in a triangle shape.

16. The photovoltaic assembly according to claim 1, wherein the heat dissipation module comprises a heat dissipation structure arranged on the backside of the photovoltaic module and a first backplate positioned on a side of the heat dissipation structure that faces away from the photovoltaic module; the first backplate is configured to be connected to the external object; the heat dissipation structure is provided with multiple heat dissipation channels, and the multiple heat dissipation channels extend along a first direction parallel to an extension direction of the photovoltaic module or along a second direction perpendicular to the extension direction of the photovoltaic module.

17. The photovoltaic assembly according to claim 16, further comprising a micro-inverter configured to convert direct current outputted by the photovoltaic module to alternate current; and the heat dissipation structure is provided with a cavity area configured to accommodate the micro-inverter.

18. The photovoltaic assembly according to claim 16, further comprising an energy storage battery configured to store electrical energy outputted by the photovoltaic module; and the heat dissipation structure is provided with a cavity area configured to accommodate the energy storage battery.

19. The photovoltaic assembly according to claim 16, further comprising a control assembly; the control assembly comprises a battery management system configured to control charging and discharging of the energy storage battery; and the heat dissipation structure is provided with a cavity area configured to accommodate the control assembly.

20. The photovoltaic assembly according to claim 19, wherein the control assembly further comprises a maximum power point tracking component configured to dynamically adjust an operating state of the photovoltaic module to ensure that the photovoltaic module keeps outputting a maximum power.
